(19) United States
(12) Patent Application Publication
(10) Pub. No.: US 2009/0323987 A1
(43) Pub. Date: Dec. 31, 2009

(54) METHOD AND APPARATUS FOR SYNCHRONIZING AUDIO LEVELS OF A DEVICE AND AN AUDIO ACCESSORY

(75) Inventors: Yuri YANG, Gurnee, IL (US); Hyun Woo Choi, Vernon Hills, IL (US)

Correspondence Address: PRASS LLP, 2661 Riva Road, Bldg. 1000, Suite 1044, ANNAPOLIS, MD, 21401, US

(73) Assignee: Motorola, Inc., Schaumburg, IL (US)

(21) Appl. No.: 12/146,659

(22) Filed: Jun. 26, 2008

(51) Int. Cl. H03G 3/00

(52) U.S. Cl. 381/109

(57) ABSTRACT

A method (200) and apparatus (100) that synchronizes audio levels of a device and an audio accessory is disclosed. In at least one embodiment, the apparatus (100) includes a housing (110) and a local speaker (130) coupled to the housing. The apparatus also includes a wireless speaker interface (180) coupled to the housing. The wireless speaker interface can be configured to send an audio signal to a remote separate speaker module wirelessly coupled to the wireless speaker interface and can be configured to send and receive volume level status data to and from the remote separate speaker module. The apparatus further includes a volume adjustment user interface (160) that can receive a user input to adjust the volume level of the remote separate speaker module. The apparatus additionally includes a controller (120). The controller can include a volume adjustment module (190) that can be configured to synchronize a volume level of the apparatus and the volume level of the remote separate speaker module by sending the volume level status data to the remote separate speaker module and by receiving the volume level status data from the remote separate speaker module. The apparatus also includes a memory (170) that can include current volume level status data based on the volume level status data sent to and received from the remote separate speaker module. The apparatus further includes a display (140) that can display an indicator (145) corresponding to the current volume level status data.

### BACKGROUND

1. Field

The present disclosure is directed to a method and apparatus for synchronizing audio levels of a device and an audio accessory. More particularly, the present disclosure is directed to synchronizing audio levels of a device with a wirelessly controllable audio accessory.

2. Introduction

Presently, people use electronic devices for playing music, for communicating with each other, and for other audio-related functions. A wireless speaker module can be wirelessly coupled to an electronic device that is a source of audio content. The wireless speaker module can provide audio playback of the content from a speaker that is not physically connected to the source electronic device. For example, a Bluetooth headset can be coupled to a mobile phone to allow a user to listen to audio from the phone over the headset.

Wireless speaker modules can include volume controls that allow a user to conveniently adjust the volume of the wireless speaker module independent of controls on the source electronic device. Even though a wireless speaker module provides volume controls, the source electronic device also provides volume controls for the audio sent to the wireless speaker module. Unfortunately, the source electronic device volume controls are not synchronized with the wireless speaker module volume controls.

For example, the volume of a headset can be controlled at both the headset and at the corresponding phone. A user may increase the volume of the phone to its maximum level, but will not hear the maximum volume if the headset is not also set to its maximum level. The user may become frustrated when the volume out of the headset is low despite the phone indicating the volume is high because the user may not realize the headset volume is set to a low level. Even though a savvy user may recognize this problem, the user still has to suffer the inconvenience of cross-referencing the volume level of the headset with the volume level of the phone to ensure each is set appropriately.

Thus, there is a need for method and apparatus that synchronizes audio levels of a device and an audio accessory.

### SUMMARY

A method and apparatus that synchronizes audio levels of a device and an audio accessory is disclosed. In at least one embodiment, the apparatus includes a housing and a local speaker coupled to the housing. The apparatus also includes a wireless speaker interface coupled to the housing. The wireless speaker interface can be configured to send an audio signal to a remote separate speaker module communicatively coupled via a wireless communication connection to the wireless speaker interface. The remote separate speaker module can have a remote separate speaker module audio amplification circuit. The remote separate speaker module can also have a volume control user interface configured to receive a user input to adjust a volume level of the audio amplification circuit. The wireless speaker interface can also be configured to send and receive volume level status data to and from the remote separate speaker module. The apparatus further includes a volume adjustment user interface coupled to the housing. The volume adjustment user interface can be configured to receive a user input to adjust the volume level of the remote separate speaker module audio amplification circuit. The apparatus additionally includes a controller coupled to the volume adjustment user interface, the wireless speaker interface, and the local speaker. The controller can include a volume adjustment module. The volume adjustment module can be configured to synchronize a volume level of the apparatus and the volume level of the remote separate speaker module by sending the volume level status data to the remote separate speaker module and by receiving the volume level status data from the remote separate speaker module. The apparatus also includes a memory coupled to the controller. The memory can include current volume level status data based on the volume level status data sent to and the volume level status data received from the remote separate speaker module. The apparatus further includes a display coupled to the controller. The display can be configured to display an indicator corresponding to the current volume level status data.

In at least another embodiment, an apparatus includes a housing, a local speaker coupled to the housing, and a wireless speaker interface coupled to the housing. The wireless speaker interface can be configured to send an audio signal to a remote separate speaker module communicatively coupled via a wireless communication connection to the wireless speaker interface. The remote separate speaker module can have a remote separate speaker module audio amplification circuit and a volume control user interface. The volume control interface can be configured to receive a user input to adjust a volume level of the audio amplification circuit. The wireless speaker interface can also be configured to send and receive volume level status data to and from the remote separate speaker module. The apparatus can further include a volume adjustment user interface coupled to the housing, a controller coupled to the volume adjustment user interface, the wireless speaker interface, and the local speaker, and a memory coupled to the controller. The volume adjustment user interface can be configured to receive a user input to adjust the volume level of the remote separate speaker module audio amplification circuit. The controller can include a volume adjustment module. The volume adjustment module can be configured to synchronize a volume level of the apparatus and the volume level of the remote separate speaker module by sending the volume level status data to the remote separate speaker module and by receiving the volume level status data from the remote separate speaker module. The volume adjustment module can also be configured to control a volume level of the local speaker based on the volume level status data received from the remote separate speaker module in response to user input at the remote separate speaker module volume control user interface. The memory can include current volume level status data based on the volume level status data sent to and received from the remote separate speaker module.

In at least another embodiment, a method includes sending audio data wirelessly to a remote separate speaker module communicatively coupled via a wireless communication connection to a wireless speaker interface, receiving user input at a local volume adjustment user interface to adjust the volume level of the remote separate speaker module, and sending volume level status data to the remote separate speaker module. The method further includes receiving volume level status data from the remote separate speaker module and synchronizing volume level data of a local apparatus and volume level data of the remote separate speaker module by merging a local apparatus volume status with a remote separate speaker module volume status based on the volume status data. The method still further includes storing current volume level status data based on the merged volume level status and displaying an indicator corresponding to the current volume level status data.

### BRIEF DESCRIPTION OF THE DRAWINGS

In order to describe the manner in which advantages and features of the disclosure can be obtained, a more particular description of the disclosure briefly described above will be rendered by reference to specific embodiments thereof which are illustrated in the appended drawings. Understanding that these drawings depict only typical embodiments of the disclosure and are not therefore to be considered to be limiting of its scope, the disclosure will be described and explained with additional specificity and detail through the use of the accompanying drawings in which:

FIG. 1 illustrates an exemplary block diagram of an apparatus in accordance with a possible embodiment; and

FIG. 2 is an exemplary flowchart illustrating the operation of an apparatus in accordance with a possible embodiment.

### DETAILED DESCRIPTION

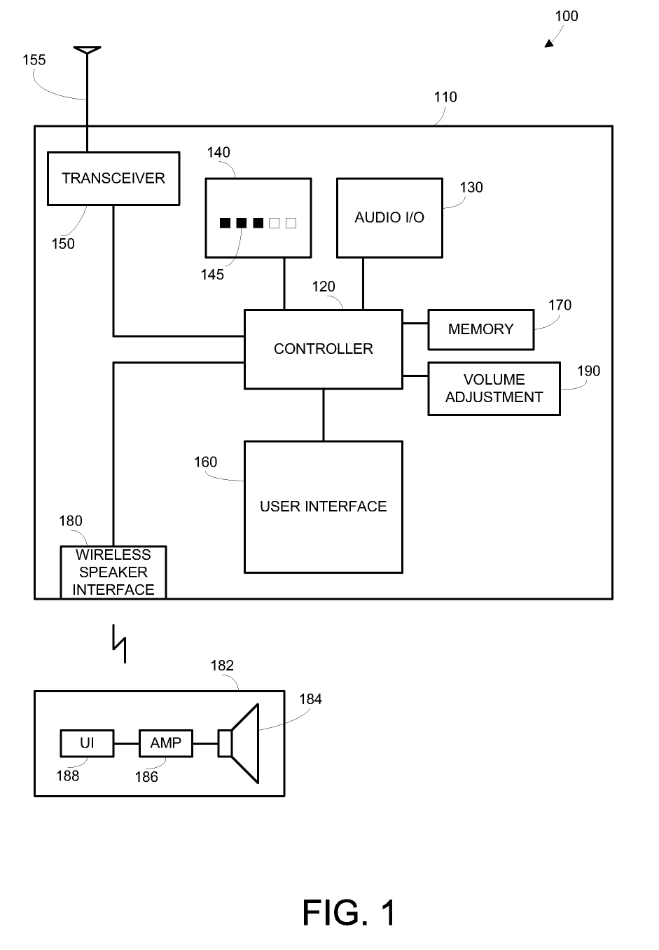

FIG. 1 is an exemplary block diagram of an apparatus 100, according to a possible embodiment. The apparatus 100 may be a wireless communication device, a wireless telephone, a cellular telephone, a personal digital assistant, a pager, a personal computer, a selective call receiver, a media player, an audio player, or any other device that can transmit and receive audio signals. The apparatus 100 can include a housing 110, a controller 120 coupled to the housing 110, audio input and output circuitry 130 coupled to the housing 110, a display 140 coupled to the housing 110, a transceiver 150 coupled to the housing 110, an antenna 155 coupled to the transceiver 150, a user interface 160 coupled to the housing 110, and a memory 170 coupled to the housing 110. The apparatus 100 can also include a wireless speaker interface 180 and a volume adjustment module 190. The wireless speaker interface 180 can be a short range wireless transceiver, a Bluetooth interface, an infrared interface, a wireless local area network interface, or any other interface that can provide wireless communication between an apparatus and a remote separate speaker. The volume adjustment module 190 can be coupled to the controller 120, can reside within the controller 120, can reside within the memory 170, can be an autonomous module, can be software, can be hardware, or can be in any other format useful for a module on an apparatus. The display 140 can be a liquid crystal display (LCD), a light emitting diode (LED) display, a plasma display, or any other means for displaying information. The transceiver 150 may include a transmitter and/or a receiver. For example, the transceiver 150 can operate on a network that is capable of sending and receiving signals, such as wireless signals. Such a network may include a wireless telecommunications network, a cellular telephone network, a Time Division Multiple Access (TDMA) network, a Code Division Multiple Access (CDMA) network, an evolution of a cellular network, a satellite communications network, or any other network that is capable of sending and receiving wireless signals.

The audio input and output circuitry 130 can be a local speaker 130. The audio input and output circuitry 130 can also include a microphone, a transducer, audio amplification circuitry, or any other audio input and output circuitry. The user interface 160 can be a volume adjustment user interface 160, such as a keypad, buttons, a touch pad, a joystick, or any other volume adjustment feature. The user interface 160 can also include additional inputs, an additional display, and/or any other features useful for providing an interface between a user and an electronic device. The memory 170 may include a random access memory, a read only memory, an optical memory, a subscriber identity module memory, or any other memory that can be coupled to an apparatus. The apparatus 100 does not require all of the illustrated elements for operation. For example, the apparatus may operate without the transceiver 150 or the antenna 155.

In operation, the wireless speaker interface 180 can send an audio signal to a remote separate speaker module 182 communicatively coupled via a wireless communication connection to the wireless speaker interface 180. The audio signal may be an analog audio signal, may be a digital audio signal, or may be any other audio signal that can be wirelessly sent to a remote wireless speaker module. The wireless speaker interface 180 may also send and receive other signals, such as microphone audio signals, data signals, and other signals. The remote separate speaker module 182 can be a wireless headset, can be an audio output device powered by a source remote from the apparatus 100, can be a volume controllable headset accessory, or can be any other remote module that can include a speaker remote from the apparatus 100. The remote separate speaker module 182 can have a speaker 184, a remote separate speaker module audio amplification circuit 186 and a volume control user interface 188. The volume control user interface 188 can be configured to receive a user input to adjust a volume level of the audio amplification circuit 186. The wireless speaker interface 180 can also be configured to send and receive volume level status data to and from the remote separate speaker module 182. The volume adjustment user interface 160 can be configured to receive a user input to adjust the volume level of the remote separate speaker module audio amplification circuit 186. The user input at the volume adjustment user interface 160 can also adjust the volume level of the local speaker 130.

The volume adjustment module 190 can be configured to synchronize a volume level of the apparatus 100 and the volume level of the remote separate speaker module 182 by sending the volume level status data to the remote separate speaker module 182 and receiving the volume level status data from the remote separate speaker module 182. For example, the volume adjustment module 190 can control the volume of the remote separate speaker module 182 by sending the volume level status data to the remote speaker module 182 and can control the volume of the local speaker 130 by receiving the volume level status data from the remote speaker module 182 or by receiving user input at the volume adjustment user interface 160. The volume adjustment module 190 can synchronize volume levels of the apparatus 100 and the remote separate speaker module 182 by sending volume level status data to the remote speaker module 182 in response to user input at the volume adjustment user interface 160 to adjust the volume level of the audio amplification circuit 186 of the remote separate speaker module 182. The volume adjustment module 190 can control a volume of the local speaker 130 based on volume level status data received from the remote separate speaker module 182 in response to user input at the remote separate speaker module volume control user interface 188. The volume adjustment module 190 can also synchronize volume levels of the apparatus 100 and the remote separate speaker module 182 by receiving volume level status data from the remote separate speaker module 182 in response to user input at the remote separate speaker module volume control user interface 188.

The memory 170 can include current volume level status data based on the volume level status data sent to and received from the remote separate speaker module 182. The volume adjustment module 190 can store the current volume level status data in the memory 170 and can update the current volume level status data in response to user input at the volume adjustment user interface 160. The volume adjustment module 190 can also update the current volume level status data in response to receiving volume level status data from the remote separate speaker module 182. A volume level of the local speaker 130 can be based on the current volume level status data and the volume level of the remote separate speaker module 182 can be based on the current volume level status data. For example, the volume adjustment module 190 can synchronize the volume levels of the apparatus 100 and the remote separate speaker module 182 by keeping each in lock step with each other. A volume level adjustment at an input on the apparatus 100 can create a synchronized volume level adjustment on the remote separate speaker module 182 and a volume level adjustment at an input on the remote separate speaker module 182 can create a synchronized volume level adjustment on the apparatus 100. The current volume level status data in the memory 170 can reflect the synchronized volume levels.

The display 140 can be configured to display an indicator 145 corresponding to the current volume level status data. The indicator 145 may be a volume bar that corresponds to the synchronized volume levels of the apparatus 100 and the remote separate speaker module 182. The indicator 145 may also be a numerical value that corresponds to the synchronized volume levels of the apparatus 100 and the remote separate speaker module 182. The indicator 145 may further be a synchronization indicator that indicates the volume levels of the apparatus 100 and the remote separate speaker module 182 are synchronized. The indicator 145 may additionally be any other useful indicator that corresponds to current volume level status data. For example, the display 140 can be configured to display an indicator 145 of the current volume level status data based on the synchronized volume levels of the apparatus 100 and the remote separate speaker module 182.

According to a related embodiment, the wireless speaker interface 180 can send an audio signal to the remote separate speaker module 182 communicatively coupled via a wireless communication connection to the wireless speaker interface 180. The wireless speaker interface 180 can also send and receive volume level status data to and from the remote separate speaker module 182. The volume adjustment user interface 160 can receive a user input to adjust the volume level of the remote separate speaker module audio amplification circuit 186. The volume adjustment module 190 can synchronize a volume level status of the apparatus 100 and the volume level status of the remote separate speaker module 182 by sending the volume level status data to the remote separate speaker module 182 and by receiving the volume level status data from the remote separate speaker module 182. The volume adjustment module 190 can control the volume of the remote separate speaker module 182 by sending the volume level status data to the remote speaker module 182 and can control the volume of the local speaker 130 by receiving the volume level status data from the remote speaker module 182. The volume adjustment module 190 can control the volume level of the local speaker 130 based on the volume level status data received from the remote separate speaker module 182 in response to user input at the remote separate speaker module volume control user interface 188. The volume adjustment module 190 can synchronize the volume level status of the apparatus 100 and the volume level status of the remote separate speaker module 182 by receiving volume level status data from the remote separate speaker module 182 in response to user input at the remote separate speaker module volume control user interface 188.

The memory 170 can store current volume level status data based on the volume level status data sent to and received from the remote separate speaker module 182. The volume level of the local speaker 130 can be based on the current volume level status data and the volume level of the remote separate speaker module 182 can be based on the current volume level status data. The volume adjustment module 190 can store the current volume level status data in the memory 170 and can update the current volume level status data in response to user input at the volume adjustment user interface 160. The volume adjustment module 190 can update the current volume level status data in the memory 170 in response to receiving volume level status data from the remote separate speaker module 182. The display 140 can display an indicator 145 corresponding to the current volume level status data.

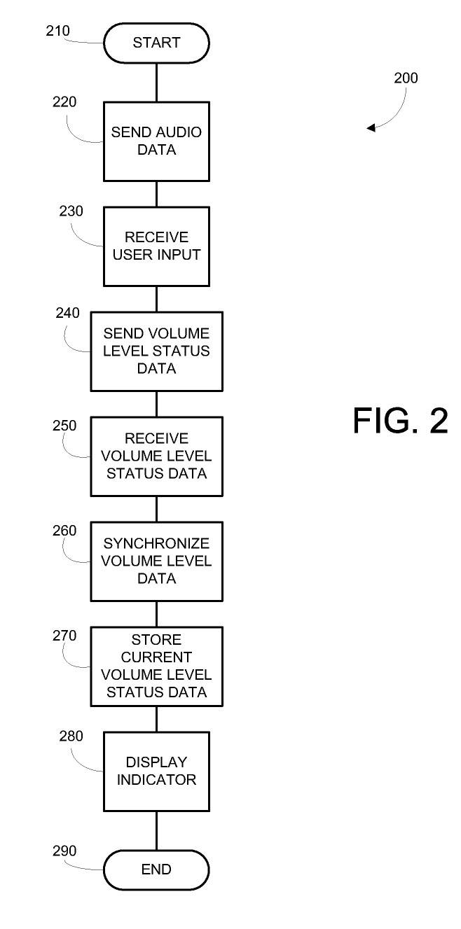

FIG. 2 is an exemplary flowchart 200 illustrating the operation of the apparatus 100 according to a possible embodiment. At 210, the flowchart begins. At 220, audio data is sent wirelessly to a remote separate speaker module communicatively coupled via a wireless communication connection to a local wireless speaker interface. At 230, user input is received at a local volume adjustment user interface to adjust the volume level of the remote separate speaker module. At 240, volume level status data is sent to the remote separate speaker module. At 250, volume level status data is received from the remote separate speaker module. At 260, volume level data of a local apparatus is synchronized with volume level data of the remote separate speaker module by merging a local apparatus volume status with a remote separate speaker module volume status based on the volume status data. For example, the most recently received or sent volume status data can be used to represent the current volume status data. As another example, volume level data of either the apparatus or the remote separate speaker module can be used as the current volume level status data when the apparatus is paired with the remote separate speaker module. As a still further example, the volume level data of each device can be averaged with each other to obtain current volume level status data. When the volume level data is synchronized, a local apparatus speaker may be controlled based on the volume level status data received from the remote separate speaker module in response to user input at the remote separate speaker module volume control user interface. At 270, current volume level status data based on the merged volume level status is stored. At 280, an indicator corresponding to the current volume level status data is displayed. At 290, the flowchart 200 ends.

Embodiments can provide for sending volume level status between an apparatus, such as a handset, and a remote separate speaker module, such as a headset accessory. If the volume is changed at the headset accessory, volume status data can be sent to the handset. If the volume is changed at the handset, volume status data can be sent to the headset accessory. Thus, both a headset and a handset indicator, such as a volume bar display, can indicate the same volume level. For example, if a volume level is at a “3” on the headset, then the handset volume level can be set to “3” when the volume levels are synchronized. If the volume level is increased from “3” to “7” on the headset, the handset volume level can be changed from “3” to “7.” Accordingly, the volume level can be controlled from either the handset or the headset. Embodiments can provide for merging of user interface control between devices, which can provide for joint control of volume level status through a single user adjustment at either device.

The method of this disclosure is preferably implemented on a programmed processor. However, the operations of the embodiments may also be implemented on a general purpose or special purpose computer, a programmed microprocessor or microcontroller and peripheral integrated circuit elements, an integrated circuit, a hardware electronic or logic circuit such as a discrete element circuit, a programmable logic device, or the like. In general, any device on which resides a finite state machine capable of implementing the operations of the embodiments may be used to implement the processor functions of this disclosure.

While this disclosure has been described with specific embodiments thereof, it is evident that many alternatives, modifications, and variations will be apparent to those skilled in the art. For example, various components of the embodiments may be interchanged, added, or substituted in the other embodiments. Also, all of the elements of each figure are not necessary for operation of the disclosed embodiments. For example, one of ordinary skill in the art of the disclosed embodiments would be enabled to make and use the teachings of the disclosure by simply employing the elements of the independent claims. Accordingly, the preferred embodiments of the disclosure as set forth herein are intended to be illustrative, not limiting. Various changes may be made without departing from the spirit and scope of the disclosure.

In this document, relational terms such as “first,” “second,” and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a,” “an,” or the like does not, without more constraints, preclude the existence of additional identical elements in the process, method, article, or apparatus that comprises the element. Also, the term “another” is defined as at least a second or more. The terms “including,” “having,” and the like, as used herein, are defined as “comprising.”

We claim:

1. An apparatus comprising:
a housing;
a local speaker coupled to the housing;
a wireless speaker interface coupled to the housing, the wireless speaker interface configured to send an audio signal to a remote separate speaker module communicatively coupled via a wireless communication connection to the wireless speaker interface, the remote separate speaker module having a remote separate speaker module audio amplification circuit and a volume control user interface configured to receive a user input to adjust a volume level of the audio amplification circuit, the wireless speaker interface also configured to send and receive volume level status data to and from the remote separate speaker module;
a volume adjustment user interface coupled to the housing, the volume adjustment user interface configured to receive a user input to adjust the volume level of the remote separate speaker module audio amplification circuit;
a controller coupled to the volume adjustment user interface, the wireless speaker interface, and the local speaker, the controller including a volume adjustment module, the volume adjustment module configured to synchronize a volume level status of the apparatus and the volume level status of the remote separate speaker module by sending the volume level status data to the remote separate speaker module and receiving the volume level status data from the remote separate speaker module;
a memory coupled to the controller, the memory including current volume level status data based on the volume level status data sent to and received from the remote separate speaker module; and
a display coupled to the controller, the display configured to display an indicator corresponding to the current volume level status data.

2. The apparatus according to claim 1, wherein the display is configured to display an indicator of the current volume level status data based on the synchronized volume levels of the apparatus and the remote separate speaker module.

3. The apparatus according to claim 1, wherein the volume adjustment module is configured to control a volume of the local speaker based on volume level status data received from the remote separate speaker module in response to user input at the remote separate speaker module volume control user interface.

4. The apparatus according to claim 1, wherein a volume level of the local speaker is based on the current volume level status data and the volume level of the remote separate speaker module is based on the current volume level status data.

5. The apparatus according to claim 1, wherein the volume adjustment module is configured to control a volume of the remote separate speaker module by sending the volume level status data to the remote speaker module and configured to control a volume of the local speaker by receiving the volume level status data from the remote speaker module.

6. The apparatus according to claim 1, wherein the volume adjustment module is configured to synchronize volume level status of the apparatus and the remote separate speaker module by sending volume level status data to the remote speaker module in response to user input at the volume adjustment user interface to adjust the volume level of the audio amplification circuit of the remote separate speaker module.

7. The apparatus according to claim 1, wherein the volume adjustment module is configured to synchronize volume levels of the apparatus and the remote separate speaker module by receiving volume level status data from the remote separate speaker module in response to user input at the remote separate speaker module volume control user interface.

8. The apparatus according to claim 1, wherein the volume adjustment module is configured to store the current volume level status data in the memory and configured to update the current volume level status data in response to user input at the volume adjustment user interface.

9. The apparatus according to claim 1, wherein the volume adjustment module is configured to store the current volume level status data in the memory and configured to update the current volume level status data in response to receiving volume level status data from the remote separate speaker module.

10. The apparatus according to claim 1, wherein the wireless speaker interface comprises a Bluetooth interface.

11. An apparatus comprising:
a housing;
a local speaker coupled to the housing;
a wireless speaker interface coupled to the housing, the wireless speaker interface configured to send an audio signal to a remote separate speaker module communicatively coupled via a wireless communication connection to the wireless speaker interface, the remote separate speaker module having a remote separate speaker module audio amplification circuit and a volume control user interface configured to receive a user input to adjust a volume level of the audio amplification circuit, the wireless speaker interface also configured to send and receive volume level status data to and from the remote separate speaker module;
a volume adjustment user interface coupled to the housing, the volume adjustment user interface configured to receive a user input to adjust the volume level of the remote separate speaker module audio amplification circuit;
a controller coupled to the volume adjustment user interface, the wireless speaker interface, and the local speaker, the controller including a volume adjustment module, the volume adjustment module configured to synchronize a volume level status of the apparatus and the volume level status of the remote separate speaker module by sending the volume level status data to the remote separate speaker module and receiving the volume level status data from the remote separate speaker module, the volume adjustment module configured to control a volume level of the local speaker based on the volume level status data received from the remote separate speaker module in response to user input at the remote separate speaker module volume control user interface; and
a memory coupled to the controller, the memory including current volume level status data based on the volume level status data sent to and the volume level status data received from the remote separate speaker module.

12. The apparatus according to claim 11, wherein a volume level of the local speaker is based on the current volume level status data and the volume level of the remote separate speaker module is based on the current volume level status data.

13. The apparatus according to claim 11, wherein the volume adjustment module is configured to control the volume of the remote separate speaker module by sending the volume level status data to the remote speaker module and configured to control the volume of the local speaker by receiving the volume level status data from the remote speaker module.

14. The apparatus according to claim 11, wherein the volume adjustment module is configured to synchronize the volume level status of the apparatus and the volume level status of the remote separate speaker module by receiving volume level status data from the remote separate speaker module in response to user input at the remote separate speaker module volume control user interface.

15. The apparatus according to claim 11, wherein the volume adjustment module is configured to store the current volume level status data in the memory and configured to update the current volume level status data stored in the memory in response to user input at the volume adjustment user interface.

16. The apparatus according to claim 11, wherein the volume adjustment module is configured to store the current volume level status data in the memory and configured to update the current volume level status data in response to receiving volume level status data from the remote separate speaker module.

17. The apparatus according to claim 11, further comprising a display coupled to the controller, the display configured to display an indicator corresponding to the current volume level status data.

18. The apparatus according to claim 11, wherein the wireless speaker interface comprises a Bluetooth interface.

19. A method comprising:
sending audio data wirelessly to a remote separate speaker module communicatively coupled via a wireless communication connection to a wireless speaker interface;
receiving user input at a local volume adjustment user interface to adjust the volume level of the remote separate speaker module;
sending volume level status data to the remote separate speaker module;
receiving volume level status data from the remote separate speaker module;
synchronizing volume level data of a local apparatus and volume level data of the remote separate speaker module by merging a local apparatus volume status with a remote separate speaker module volume status based on the volume status data;
storing current volume level status data based on the merged volume level status; and
displaying an indicator corresponding to the current volume level status data.

20. The method according to claim 19, further comprising controlling a volume level of a local apparatus speaker based on the volume level status data received from the remote separate speaker module in response to user input at the remote separate speaker module volume control user interface.
